(19) United States
(12) Patent Application Publication
(10) Pub. No.: US 2022/0115609 A1
(43) Pub. Date: Apr. 14, 2022

(54) NANOELECTRONIC DEVICE AND METHOD FOR PRODUCING THEREOF

(71) Applicant: GEORG-AUGUST-UNIVERSITÄT GÖTTINGEN, Göttingen (DE)

(72) Inventors: Jakob LENZ, Munich (DE); Thomas WEITZ, Munich (DE)

(73) Assignee: Georg-August-Universität Göttingen Stiftung Öffentlichen Rechts, Göttingen (DE)

(21) Appl. No.: 17/299,857

(22) PCT Filed: Nov. 27, 2019
(86) PCT No.: PCT/EP2019/082693

§ 371 Date: Jun. 4, 2021

(30) Foreign Application Priority Data
Dec. 10, 2018 (DE) 10 2018 221 361.5

(51) Int. Cl. H01L 51/05

(52) U.S. Cl. CPC H01L 51/057; H01L 51/0554; H01L 51/0537

(57) ABSTRACT

The present invention relates to a nanoelectronic device, comprising a substrate layer (10), a first electrode layer (12) disposed on the substrate layer (10), a dielectric layer (16) disposed on the first electrode layer (12), a second electrode layer (18) disposed on the dielectric layer (16), wherein the dielectric layer (16) and the second electrode layer (18) are dimensioned such that at least one protruding portion (18a, 18b) of the second electrode layer (18) is formed in which the second electrode layer (18) extends beyond the dielectric layer such that opposing faces of the first and second electrode are formed (16), at least one semiconductor layer (20) disposed between the first electrode layer (12), one of the protruding portions (18a, 18b) of the second electrode layer (18) and the dielectric layer (16); and a gating arrangement (22) in contact with at least the semiconductor layer (20) as well as the first (12) and second (18) electrode layers.

The present invention relates to a nanoelectronic device, comprising a substrate layer, a first electrode layer disposed on the substrate layer, a dielectric layer disposed on the first electrode layer, a second electrode layer disposed on the dielectric layer, wherein the dielectric layer and the second electrode layer are dimensioned such that at least one protruding portion of the second electrode layer is formed in which the second electrode layer extends beyond the dielectric layer such that opposing faces of the first and second electrode are formed, a semiconductor layer disposed between the first electrode layer, at least one of the protruding portions of the second electrode layer and the dielectric layer, and a gating arrangement in contact with at least the semiconductor layer. Furthermore, the present invention relates to a method of producing such a device.

While organic or perovskite based materials semiconductors have been found to be promising components for novel flexible electronics such as displays and sensors with their large-scale processability via printing and the inherent flexibility of organic materials being two key advantages in this context, attributes that do usually not come to mind when discussing organic semiconductor materials are high current densities, large transconductances, low-power operation and low supply voltages which on the other hand are common in highly integrated nanoscale transistors. Therefore, organic semiconductors are usually not thought to show outstanding performance in certain highly-integrated sub-100 nm electronic devices such as transistors.

More specifically, whereas for example state of the art single-crystalline materials such as single walled carbon nanotubes (SWCNT), MoS2 or inorganic semiconductors are the materials of choice for field-effect transistors that are able to sustain current densities above MA/cm², organic transistors are currently only able to operate at tens of kA/cm². An example for the use of carbon nanotubes in transistors is presented in “Vertical Electrolyte-Gated Transistors Based on Printed Single-Walled Carbon Nanotubes”, Rother et.al., ACS Appl. Nano Mater. 2018, 1, 3616-3624, while an overview over organic transistors is given in “Vertical Organic Transistors”, Lüssem et. al., 2015, J Phys.: Condens. Matter 27 5443003.

While high current densities are crucial for realizing highly integrated, high-performance electronics, low-power operation on the other hand is critical for the operation in handheld devices or neural networks. In the latter, the energy per switching event is required to be reduced down to the sub-pJ regime, implying the need for high on-state conductance, large current modulation ratios and the capability for low-voltage operation.

Up to now, organic or perovskite based materials have not been able to meet these diverse demands and can either drive high currents, for example the above-mentioned SWCNTs, or have a large on/off-ratios, while a manufacturing of devices showing both of the above-mentioned desired properties has not yet been achieved.

Furthermore, not only for organic or perovskite based materials, but also for inorganic semiconductor materials there is a continuous demand to improve the balance between current density on the one hand and low-power operation and switching characteristics on the other hand.

It is therefore the object of the present invention to provide a nanoelectronic device that is based on a vertical layer structure and enables gated semiconductors to drive high currents combined with outstanding on/off ratios. The gating arrangement of the device according to the invention for this purpose may comprise a liquid electrolyte, an ionic gel or a solid state dielectric material.

In some embodiments of the device according to the present invention, currents in the order of MA/cm² combined with on/off ratios of 10⁸ can be achieved. Furthermore, the nanoelectronic device of the present invention can be scaled down to channel lengths of below 50 nm and nanoscopic device footprints of 2×80×80 nm² and below allowing their use in highly integrated circuits.

This object is achieved by providing a nanoelectronic device in which a dielectric layer is sandwiched between first and second electrode layers wherein the second electrode layer comprises at least one protruding portion which extends beyond the dielectric layer in its width direction such that opposing faces of the first and second electrode layers are formed. Subsequently a semiconductor is disposed in the resulting space between the first electrode layer, at least one of the protruding portions of the second electrode layer and the dielectric layer such that a well-defined channel with small dimensions is formed by the semiconductor layer between the first and second electrode layers and bordered to one side by the dielectric layer.

By using for example an electrolyte in contact with at least the semiconductor layer for gating the nanoelectronic device according to the invention, due to the large capacitance of electrolytes typically used for such purposes, the device according to the invention can be operated at very small gate-source voltages, for example below 2V. While such electrolyte gating has been established in the past as a reliable method to enable large gate coupling, together with the novel layout of the semiconductor layer, the nanoelectronic device according to the invention does not show any signs of contact resistance and high on/off current ratios can be observed.

While in principle, vertical field effect transistors (VOFETs) have been established as a promising approach to achieve a nanoscopic source-drain contact separation and a nanoscopic footprint without the need for high-resolution pattering, only through the inclusion of the dielectric layer of the nanoelectronic device according to the present invention as well as the resulting shape of the layer of the semiconductor, better control of the channel with the electrolyte is facilitated, since the ions have to diffuse a smaller distance to control the entire channel.

Thus, by means of the combination of short channel lengths with electrolyte gating, low-voltage, high on-state current densities and large transconductances are achieved in a novel way, which can however in a similar manner also be achieved with other gating arrangements as discussed above. Furthermore, because of the fast diffusion of the electrolyte into the semiconductor layer, improved switching properties can be achieved and by suitably choosing the properties of the dielectric layer as well as the thickness and width of the semiconductor layer, the properties of the nanoelectronic device can be fine-tuned according to the prerequisites of the respective application. Additionally and as will be discussed below, the device according to the invention can also be manufactured in an efficient and precise way by means of known and established techniques.

In an exemplary embodiment, the width of the dielectric layer as measured in the plane of the substrate layer can be larger than the width of at least one semiconductor layer. In a further embodiment the width of the least one semiconductor layer as measured in the plane of the substrate layer can be smaller than its thickness perpendicular to the plane of the substrate layer. In a further embodiment the width of the least one semiconductor layer as measured in the plane of the substrate layer can range from 1 to 200 nm, preferably from 2 to 100 nm, more preferably from 5 to 90 nm. By providing the least one semiconductor layer with such dimensions, a narrow channel and thus fast switching turnarounds can be achieved, while the maximum achievable current through the semiconductor layer is also partially determined by its width.

The semiconductor layer can be constituted of or comprise any suitable semiconductor material, for example an inorganic semiconductor, however, preferably an organic semiconductor material or a perovskite based material is used for the semiconductor layer. For example the semiconductor layer can comprise at least one of the group consisting of PDPP, P3HT, Indacenodithiophene-co-benzothiadiazole, (3-alkylthiophen-2-yl)thieno(3,2-b)thiophene, Poly(phenylene vinylene), Polyfluorene or Poly(-vinylcarbazole), Perylene diimides, Naphtalene diimides, Hereroacenes, Rubrene, Perovskite, BP3T, F8, F8BT, C8BTBT and mixtures of p-type and n-type semiconductors.

Similarly, the dielectric layer may consist of or comprise any suitable dielectric material which can be chosen according to the preferred properties of the device according to the invention or for its ease of manufacturing. For example, the dielectric layer may comprise at least one out of the group consisting of SiO₂, SiO, Si₃N₄, Al₂O₃, TiO₂, SiOF, Cytop, PS, PMMA, Parylen, PVA, PVP, hexagonal BN and/or may consist of or comprise the same material as the substrate layer.

Furthermore, one or more additional conductive layers may be provided between the substrate layer and the first electrode layer and/or between the first electrode layer and the dielectric layer and/or between the dielectric layer and the second electrode layer. Said layers can for example serve to improve adhesion between the respective layers and their materials can be chosen accordingly.

While the nanoelectronic device according to the invention may assume different geometries and may for example comprise square-shaped first and second electrode layers, it can be beneficial when both the first electrode layer and the second electrode layer are each formed in rectangular shapes intersecting at an angle to form an overlap area when viewed towards the substrate, wherein the angle might preferably be 90 degrees. In such geometries, one or two semiconductor layers can be provided on either side in the width direction of the second electrode, for example over the entire width of the first electrode. In any case, the respective widths of the first and second electrodes may be equal or different.

As mentioned above, one of the advantages of the device according to the invention can be its scalability to very small dimensions, for example, the overall thickness of the first electrode layer, the dielectric layer and the second electrode layer may be smaller than 100 nm, preferably smaller than 50 nm. Alternatively or additionally, the thickness of the dielectric layer itself may for example range from 1 to 20000 nm, preferably from 2 to 2000 nm and more preferably from 5 to 1500 nm.

While in theory the nanoelectronic device according to the invention may solve different purposes and could thus be contacted in a different manner, in order to provide the functionality of a transistor, one of the first electrode layer and the second electrode layer may be contacted to serve as a source, the other of the first electrode layer and the second electrode layer may be contacted to serve as a drain and the gating arrangement may be contacted to serve as a gate, such that the devices adapted to serve as a field-effect transistor.

According to a second aspect of the invention, a method for producing a device according to the invention is provided, comprising the steps of providing a substrate layer, depositing a first electrode layer on the substrate layer, depositing a dielectric layer on the first electrode layer, depositing a second electrode layer on the dielectric layer, selectively partially removing the dielectric layer such that at least one protruding portion of the second electrode layer is formed in which the second electrode layer extends beyond the dielectric layer, depositing a semiconductor, preferably an organic or perovskite based semiconductor layer between the first electrode layer, the protruding portion of the second electrode layer and the dielectric layer such that opposing faces of the first and second electrode are formed, and depositing a gating arrangement in contact with at least the semiconductor layer and may additionally be also in contact with the first and/or second electrode layers.

Since the depositing of the dielectric layer as well as its partial removal is a well-established and precisely controllable method step, the method according to the invention can be employed especially efficiently, since the semiconductor layer is deposited only after the first and second electrode layers as well as the dielectric layer have been produced.

In particular, the step of the selective partial removal of the dielectric layer may comprise HF-etching.

Additionally or alternatively, the step of depositing the semiconductor layer may comprise the sub-steps of spin-coating the structure formed in the step of partially removing the dielectric layer with the semiconductor material, and reactive ion-etching the semiconductor material, for example using oxygen.

Subsequently to the depositing of the gating arrangement, the method according to the invention may further comprise a step of contacting the first or second electrode layer to serve as a source, contacting the first or second electrode layer to serve as a drain and contacting the gating arrangement to serve as a gate.

As already briefly mentioned above, the method according to the invention may further comprise one or more additional steps of depositing one or more additional conductive layers between the substrate layer and the first electrode layer and/or between the first electrode layer and the dielectric layer and/or between the dielectric layer and the second electrode layer.

The device according to the invention, possibly produced by the method according to the invention, may be used for example as a transistor structure, a memristive element, a light emitting device or an electrically pumped solid state injecting lasing device.

Further advantages and features of the present invention will become even clearer from the following description of embodiments of the invention, when viewed together with the attached drawings. These drawings show:

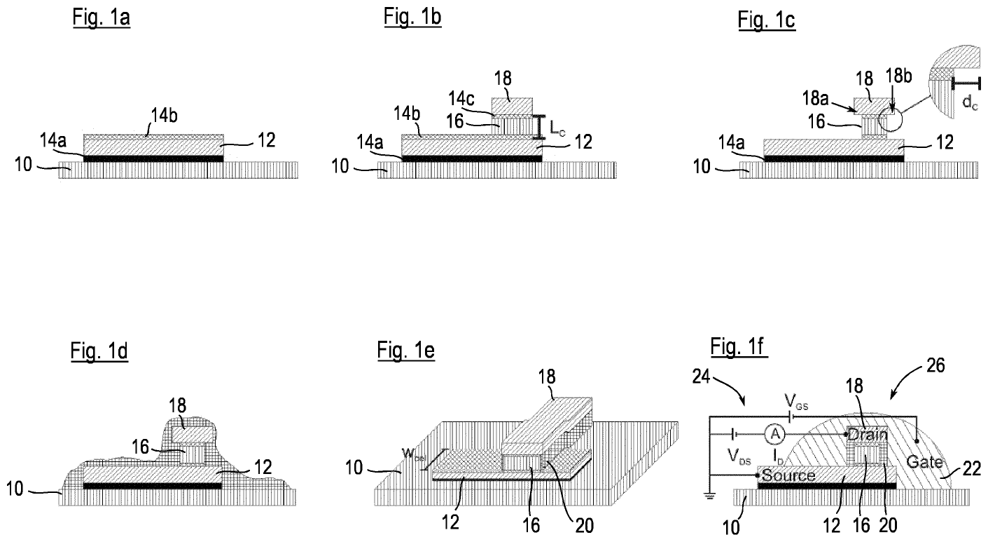

FIGS. 1 a to 1f steps of the method for producing a nanoelectric device according to the invention;

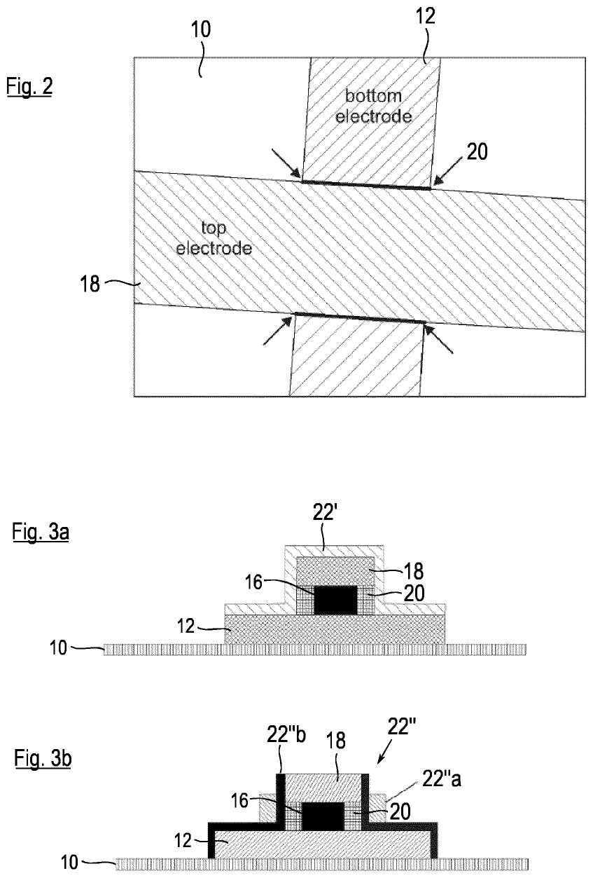

FIG. 2 the device manufactured in FIGS. 1a to 1f in top view;

FIGS. 3a and 3b alternative embodiments of the device produced in FIG. 1; and

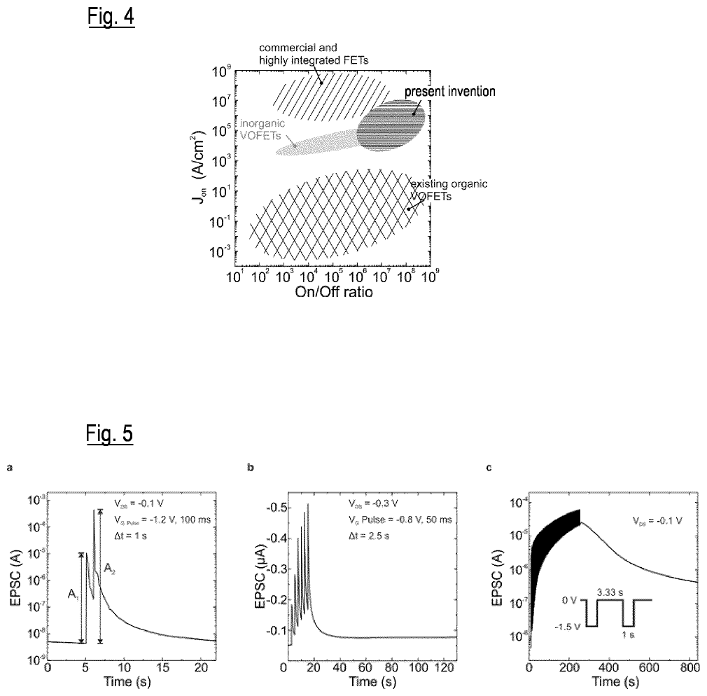

FIG. 4 a comparison of on-state current densities and on-off ratios for different vertical and planar transistors;

FIG. 5 short and long term synaptic plasticity of electrolyte gated PDPP VOFETs according to the invention; and

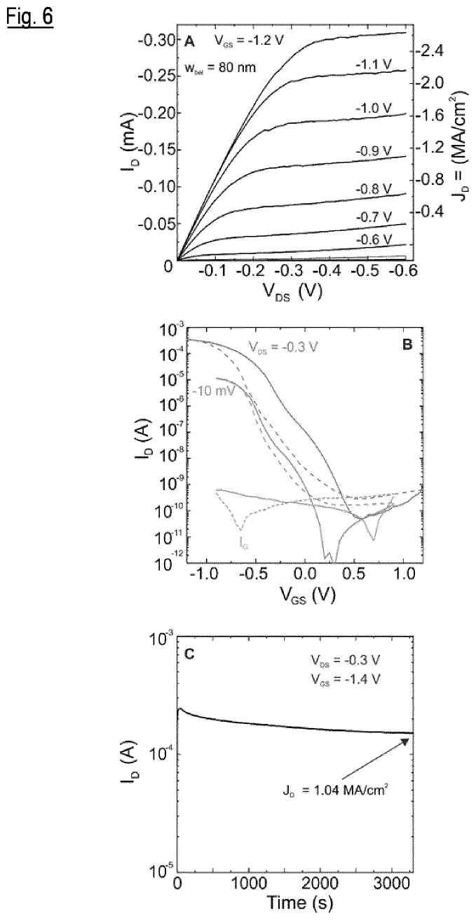

FIG. 6 further characteristics of electrolyte gated PDPP VOFETs according to the invention.

In FIG. 1a, during a first step of the method for producing a nanoelectronic device according to the invention, on a substrate layer 10, a first electrode layer 12 has been deposited. The substrate layer 10 may for example be made from Si/SiO₂, while the first electrode layer 12 may be comprised of gold, palladium and/or other conductive materials, in particular metals. Between the substrate layer 10 and the first electrode layer 12, a thin layer 14a of chrome has been deposited, while on top of the first electrode layer 12, a layer of titanium 14b has been deposited, the respective layers 14a and 14b serving to improve the adhesive properties between their neighboring layers.

In FIG. 1b, on top of the titanium layer 14b, a dielectric layer 16 has been deposited, which may be made from the same material as the substrate layer 10, in the shown example SiO₂. On top of said dielectric layer 16, another layer of titanium 14c is deposited, on top of which in turn a second electrode layer 18 again made from gold, palladium and/or other conductive materials has been deposited. The distance between the first electrode layer 12 and the second electrode layer 18, i.e. the overall thickness of the titanium layers 14b, 14c and the dielectric layer 16 is denoted with L_{c} and referred to as the channel length. This channel length L_{c} may for example range from 1 to 20000 nm, preferably from 2 to 2000 nm and more preferably from 5 to 1500 nm and at least partially determines the maximum achievable current through the semiconductor layer.

While the geometrical shapes of the first and second electrode layers 12 and 18 as well as the dielectric layer 16 can be chosen from a wide array of possible shapes, in the present example, the first and second electrode layers 12 and 18 are both of rectangular shapes with respective widths and lengths which can for example be understood from FIG. 1 e, in which the width of the first electrode layer 12 is exemplarily denoted wbel. Typical values for wbel can range from 1 nm to 10 mm, preferably from 5 nm to 100 μm, more preferably from 10 nm to 10 μm. For the purpose of patterning the electrode layers 12 and 18, electron beam lithography may be employed.

Subsequently, parts of the dielectric layer 16 as well as the neighboring titanium layers 14b and 14c are selectively removed as can be seen in FIG. 1c such that protruding portions 18a and 18b are formed on both sides of the second electrode layer 18 which extend beyond the dielectric layer 16 by a distance of dc. In the present example, for the partial removal of the dielectric layer 16 and the titanium layers 14b and 14c, for example 1% HF-acid can be used to form under-etched top contacts. The magnitude of d_{c} and the resulting channel area of A_{ch}=2*w_{bel}*d_{c} can be controlled via the etching time and smaller values of d_{c} enable better control of the channel with the below-described electrolyte, since the ions have to diffuse a smaller distance to control the entire channel.

As can be seen in FIG. 1d, after the step of the selectively partially removing the dielectric layer 16 in order to form the protruding portions 18a and 18b, the whole structure is spin-coated with an organic semiconductor material which subsequently is mostly removed again, for example by means of reactive ion etching (RIE), in such a manner that since the protruding portions 18a and 18b serve as an etching mask, only between the protruding portions 18a and 18b of the second electrode layer, the titanium layers 14b and 14c, the dielectric layer 16 and the first electrode layer 12, i. e. in the pockets with size d_{c}* L_{c}*w_{bel}, the organic semiconductor material remains and forms semiconductor layers 20, with an outer surface which is flush with the outer faces of the protruding portions 18a and 18b of the second electrode layer 18. The semiconductor material used for this purpose may for example be diketopyrrolopyrrole-terthiophene donor-accepted polymer (PDPP).

Subsequently, an electrolyte 22 is deposited on top of the semiconductor structure in a manner that it is in contact with the first and second electrode layers 12 and 18 as well as the semiconductor layer 20 to serve as the gating arrangement in the sense of the invention. In this configuration, and as can be seen in FIG. 1f as well, the individual components of the structure can be contacted with circuitry 24, wherein the first electrode 12 is contacted as a source and grounded, the second electrode 18 is contacted as a drain and the electrolyte 22 is contacted as a gate, such that an organic field effect transistor 26 is formed. Possible materials for the electrolyte 22 include the ionic liquid 1-ethyl-3-methylimidazolium bis(trifluoromethylsulsonyl)imid [EMIM][TFSI].

Said structure 26 produced in FIGS. 1a to 1f is again shown in top view in FIG. 2, wherein it can be seen that the layers 20 of organic semiconductor material are very narrowly confined to the edges of the second (top) electrode 18 layer across the width of the first (bottom) electrode layer 12.

It shall further be mentioned that similar embodiments of the invention as produced in FIGS. 1a to 1f may for example also be used as light emitting devices or solid state injecting lasing devices, for the purpose of which the first electrode and/or the second electrode may simultaneously serve as a semitransparent mirror in order to achieve population inversion and thus lasing properties of the structure. Furthermore, in this specific case of serving as an electrically pumped solid state injecting lasing device, the thickness of the dielectric layer of device according to the invention has to be chosen to match the known scaling dimensions for resonators of laser cavities.

FIGS. 3a and 3b show alternative embodiments of the device produced in FIG. 1, which differ from said embodiment only in the choice of their gating arrangements 22′ and 22″, respectively. Thus, for a description of the remaining components such as the first and second electrode layers 12 and 18 as well as the dielectric layer 16, it is referred to the description of FIGS. 1a to 1f. These components are also provided with identical reference numerals as in for example in FIG. 1f.

The device of FIG. 3a instead of having a liquid electrolyte 22 as gating arrangement comprises an ionic gel in contact with the semiconductor layer 20 as well as the first 12 and second 18 electrode layers to serve as the gating arrangement in the sense of the invention by having the ions diffuse into the semiconductor layer in on-state. While this embodiment operates in a similar way as the embodiment of FIGS. 1a to 1f, the device of FIG. 3b is not based on physical diffusion of the electrolyte or the ions of the gel into the semiconductor layer.

Rather, the embodiment of FIG. 3b is provided with a two-part gating arrangement 22″ comprising a dielectric coating layer 22″b covering the first and second electrode layers 12, 18 as well as the organic semiconductor layer 20 and a gate electrode 22″a disposed outside the coating 22″b in the vicinity of the semiconductor layer 20. In this case, the switching between on and off states of the device is not caused by an electrolyte or ions diffusing in and out of the semiconductor layer but rather by an electric field effect due to a voltage applied to the gate electrode 22″a. In the embodiment of FIG. 3b, the dielectric coating layer 22″b may be made of the same or a different dielectric material as the dielectric layer 16, such as SiO₂, and the gate electrode 22″a may be made of the same material as at least one of the first and second electrode layers 12 and 18 or another electrically conductive material.

Finally, in FIGS. 4 to 6, performance parameters of exemplary devices according to the invention are shown, wherein FIG. 4 shows a comparison of on-state current densities an on-off ratios for different vertical and planar transistors, FIG. 5 shows short and long term synaptic plasticity of electrolyte gated PDPP VOFETs according to the invention; and FIG. 6 shows further characteristics of electrolyte gated PDPP VOFETs according to the invention.

FIG. 4 summarizes and compares the device performances of several state-of-the-art VOFETs and lateral FETs with respect to their on-state current density and on-off ratio. The performance of electrolyte gated PDPP-based VOFETs according to the invention exceeds the best vertical organic transistors and is in fact comparable to inorganic vertical transistors based on e.g. GaAs. This is particularly surprising, since VOFETs according to the invention were operated only at drain-source voltage of −0.3 V and −10 mV, respectively, which is at least a factor 4 smaller than the operation voltage of inorganic vertical FETs. Furthermore, the VOFETs according to the invention also perform well compared to SWCNT, MoS₂ and FIN-FET devices. Additionally, the outstanding properties are not limited to PDPP and are comparable for different polymers, e.g. P3HT, which demonstrates that this device architecture can be expected to be suitable for a wide range of semiconductors. Finally, the transistors according to the invention show large transconductances of above 5000 S/m.

FIG. 6 shows characteristics of electrolyte gated PDPP VOFETs according to the invention. In an electrolyte gated VOFET according to the invention with a channel area of A_{ch}=1.6×10⁻¹¹ m², a channel length of L_{c}=40 nm and a bottom electrode width of w_{bel}=100 μm, the total resistance Rₜₒₜ in the on-state with a maximum on current of Iₒₙ=5.6 mA at a drain-source voltage V_{DS}=−0.3 V is Rₜₒₜ=54 Ω. Control experiments revealed similar total resistances for only the measurement setup including contact resistances.

Apparently, the channel resistance seems to be almost negligible in this specific device geometry and Iₒₙ is predominantly limited by contact and lead resistances. To find an upper limit for Iₒₙ, the relative resistance of the channel has been increased by reducing the channel area A_{ch} to a nanoscopic 2×80×80 nm² (the resistance of the current leads stays the same compared with the previously described devices, note that the channel length L_{c} was left unchanged). The maximum current density for these nanoscopic transistors is J_{-0.3}v=2.7 MA/cm² (on-off ratio 10⁷) and J₋₁₀ mV=89.9 kA/cm², at V_{DS}=−0.3 V and −10 mV respectively (see FIGS. 4a and b).

As shown in FIG. 4c, transistors according to the invention can be operated continuously for at least 50 min at MA/cm² current densities without significant degradation of the current. It is assumed that the stability at these high current densities stems from the favorable device geometry, since the small channel width and length provide intimate contact of the semiconductor to the source and drain contacts as well as to the SiO₂, which act as heat sink that allow for a rapid dissipation of the developing heat. Additional heat might be dissipated by the ionic liquid that has entirely penetrated the semiconductor. This is also probably the reason that neither a self-heating induced N-shaped negative differential resistance reported for inorganic transistors nor a S-shaped negative differential resistance recently presented for organic permeable-base transistors was found in the devices according to the invention.

The large on-state conductances, high on-off ratios and low gate-source operational voltages make the device design according to the invention also suitable for ultra-low power electronics. For example, these devices can be operated at a drain-source voltage of only 10 μV where they still obtain on/off ratios of 10². Such low power operation is especially relevant for applications in artificial neural networks as memristive devices. More specifically, the VOFETs according to the invention combine the ability for low voltage operation with a small footprint, large on/off ratio, high switching speed, long-term stability of the electrical performance and the use of electrolyte gating.

To prove the general usability of these devices in this field, artificial synaptic behavior with short- and long-term plasticity (STP and LTP) is shown in FIG. 5. As previously reported for electrolyte gated OFETs, the contact to the liquid electrolyte can be seen as the presynaptic- and the source electrode as the postsynaptic terminal. Upon a voltage pulse at the gate electrode (corresponding to a presynaptic potential spike), the increase in drain current can be viewed as the excitatory post-synaptic current (EPSC), which represents the synaptic strength.

Before a presynaptic spike, the anions and cations are randomly distributed in the liquid electrolyte. A short negative voltage pulse causes anions to penetrate into the bulk of the semiconductor, leading to an accumulation of free holes in the semiconducting channel. These charge carriers contribute to the EPSC upon an applied source drain voltage. After the presynaptic spike there is no driving force for the ions to remain in the semiconductor, hence they slowly return to a random distribution and the EPSC decays. The EPSC change over time is regarded as synaptic plasticity that can be distinguished in STP and LTP.

While STP is more important for application of memristive elements in computational applications, LTP is more important in learning. With the novel device geometry according to the present invention the relative strength of

STP and LTP can be tuned via the device design, thus making the layout suitable for a wide range of potential applications. Paired-pulse facilitation (PPF) is a possibility to simulate STP. FIG. 5a shows the EPSC where the amplitude of the second postsynaptic response A2=608 μA is amplified compared to the first one A1=10.5 μA by a factor of 58. Since before the second presynaptic spike the ions have not returned to a complete random distribution, these residual ions contribute to the second presynaptic spike resulting in an increased EPSC.

For long-term memory formation it is necessary to transform STP to LTP. LTP in electrolyte gated VOFETs according to the invention is shown in FIG. 5b. After six pulses (−0.8 V, 50 ms) with an inter-spike interval of 2.5 s, an increase of the EPSC after each pulse and an obvious nonvolatile channel current is measured, which constitutes memory formation. Another method to realize LTP is by increasing the magnitude of the gate pulse. For applications that rely on LTP, storage of the state for more than 10³ s would be favorable.

The magnitude of the EPSC and consequently LTP can easily be increased in the devices according to the invention by enlarging d_{c} of the semiconducting layer, which in turn is determined by the amount of underetching of the top electrode as discussed above.

An extreme case is shown in FIG. 5c where only PDPP is sandwiched between the electrodes. In these devices the ESPC is increased by a factor of almost 3000 after the last spike and was still increased by a factor of 50 after 10 min. The larger channel area and therefore the larger volume for potential bulk gating results in an increased memory formation compared to smaller channel areas and thus enhanced LTP compared to devices with shorter d_{c}. Furthermore, in FIG. 5c, the EPSC is triggered by 73 pulses (−1,5V, 1 s) at an inter-spike interval of 3.33 s for an electrolyte gated VOFET without SiO₂ spacer and only PDPP between the two electrodes.

Besides synaptic plasticity, also the minimum energy required for a switching operation is a critical factor for possible integration of memristors into complex neuronal networks. Given the large on-state current densities, high on-off ratios and low operation voltages of the devices according to the invention, the currents and also switching energies can be tuned across a wide range depending on the choice of applied voltages. The minimal switching energies that have achieved so far are in the 10⁻¹³−10 ⁻¹⁴ J range, where V_{DS}=100 μV and V_{GS}=−0.4 to −1.2 V were used.

Such low switching energies are already below what is currently used in CMOS neuromorphic devices, and only one magnitude larger than the 10 fJ per event used in the brain. Furthermore, the here obtained switching energies are only a factor of 100 larger compared to the best reported switching energies that have been obtained in core-sheath nanowires.

1. Nanoelectronic device, comprising:
a substrate layer;
a first electrode layer disposed on the substrate layer;
a dielectric layer disposed on the first electrode layer;
a second electrode layer disposed on the dielectric layer;
wherein the dielectric layer and the second electrode layer are dimensioned such that at least one protruding portion of the second electrode layer is formed in which the second electrode layer extends beyond the dielectric layer such that opposing faces of the first and second electrode layers are formed;
at least one semiconductor layer disposed between the first electrode layer, one of the protruding portions of the second electrode layer and the dielectric layer; and
a gating arrangement in contact with at least the semiconductor layer.

2. Device according to claim 1, wherein the gating arrangement comprises a liquid electrolyte, an ionic gel or a solid state dielectric material.

3. Device according to claim 1, wherein the width of the dielectric layer as measured in the plane of the substrate layer is larger than the width (d_{c}) of the at least one semiconductor layer and/or the width of the semiconductor layer as measured in the plane of the substrate layer is smaller than its thickness perpendicular to the plane of the substrate layer and/or the width of the least one semiconductor layer as measured in the plane of the substrate layer ranges from 1 to 200 nm.

4. Device according to claim 1, wherein the semiconductor layer comprises an organic or Perovskite based semiconductor material.

5. Device according to claim 1, wherein the dielectric layer comprises at least one of the group consisting of SiO₂, SiO, Si₃N₄, Al₂O₃, TiO₂, SiOF, Cytop, PS, PMMA, Parylen, PVA, PVP, hexagonal BN and/or consists of or comprises the same material as the substrate layer.

6. Device according to claim 1, wherein one or more additional conductive layers are provided between the substrate layer and the first electrode layer and/or between the first electrode layer and the dielectric layer and/or between the dielectric layer and the second electrode layer.

7. Device according to claim 1, wherein both the first electrode layer and the second electrode layer are each formed in a rectangular shape and intersect at an angle to form an overlap area when viewed towards the substrate.

8. Device according to claim 1, wherein;
(a) the overall thickness of the first electrode layer and/or the dielectric layer and/or the second electrode layer is smaller than 100 nm, and/or
(b) the thickness of the dielectric layer itself ranges from 1 to 20000 nm.

9. Device according to claim 1, wherein one of the first electrode layer and the second electrode layer is contacted to serve as a source, the other of the first electrode layer and the second electrode layer is contacted to serve as a drain and the gating arrangement is contacted to serve as a gate, such that the device is adapted to serve as a field-effect transistor.

10. Method for producing a device according to claim 1, comprising the steps of:
(a) providing a substrate layer;
(b) depositing a first electrode layer on the substrate layer;
(c) depositing a dielectric layer on the first electrode layer;
(d) depositing a second electrode layer on the dielectric layer;
(e) selectively partially removing the dielectric layer such that at least one protruding portion of the second electrode layer is formed in which the second electrode layer extends beyond the dielectric layer such that opposing faces of the first and second electrode layers are formed;
(f) depositing an semiconductor layer between the first electrode layer, one of the protruding portions of the second electrode layer and the dielectric layer; and
(g) depositing a gating arrangement in contact with at least the semiconductor layer as well as the first and second electrode layers.

11. Method according to claim 10, wherein step (e) comprises HF-etching.

12. Method according to claim 10, wherein step (f) comprises the sub-steps of:
(f1) spin-coating the structure formed in step (e) with the semiconductor material; and
(f2) reactive ion etching the semiconductor material, for example using oxygen.

13. Method according to claim 10, after step (g) further comprising a step of:
(h) contacting the first or second electrode layer to serve as a source, contacting the first or second electrode layer to serve as a drain and contacting the gating arrangement to serve as a gate.

14. Method according to claim 10, further comprising one or more additional steps of depositing one or more additional conductive layers between the substrate layer and the first electrode layer and/or between the first electrode layer and the dielectric layer and/or between the dielectric layer and the second electrode layer.

15. Method of using a device of claim1 as a transistor structure, a memristive element, a light emitting device or a solid state injection lasing device.

16. Device according to claim 3, wherein the width of the dielectric layer as measured in the plane of the substrate layer is larger than the width (d_{c}) of the at least one semiconductor layer and/or the width of the semiconductor layer as measured in the plane of the substrate layer is smaller than its thickness perpendicular to the plane of the substrate layer and/or the width of the least one semiconductor layer as measured in the plane of the substrate layer ranges from 5 to 90 nm.

17. Device according to claim 4, wherein the semiconductor layer comprises at least one semiconductor material selected from the group consisting of P3HT, Indacenodithiophene-co-benzothiadiazole, (3-alkylthiophen-2-yl)thieno(3,2-b)thiophene, Poly(phenylene vinylene), Polyfluorene or Poly(-vinylcarbazole), Perylene diimides, Naphtalene diimides, Hereroacenes, Rubrene, perovskite, BP3T, F8, F8BT, C8BTBT and mixtures of p-type and n-type semiconductors.

18. Device according to claim 7, wherein the angle is 90°.

19. Device according to claim 8, wherein:
(a) the overall thickness of the first electrode layer and/or the dielectric layer and/or the second electrode layer is smaller than 50 nm, and/or
(b) the thickness of the dielectric layer itself ranges from 5 to 1500 nm.

20. Method of claim 15, wherein the first electrode and/or the second electrode is configured as a semitransparent mirror.
